(19) United States
(12) Patent Application Publication
(10) Pub. No.: US 2015/0268274 A1
(43) Pub. Date: Sep. 24, 2015

(54) PROBE MODULE FOR DETECTING CONTACT PERFORMANCE

(71) Applicant: SHENZHEN CHINA STAR OPTOELECTRONICS TECHNOLOGY CO., LTD., Shenzhen, Guangdong (CN)

(72) Inventors: Tao Song, Shenzhen (CN); Guodong Zhao, Shenzhen (CN); Ming Liu, Shenzhen (CN); Tao Ma, Shenzhen (CN)

(73) Assignee: SHENZHEN CHINA STAR OPTOELECTRONICS TECHNOLOGY CO., LTD., Shenzhen, Guangdong (CN)

(21) Appl. No.: 14/241,402

(22) PCT Filed: Jan. 17, 2014
(86) PCT No.: PCT/CN2014/070832

§ 371 Date: Feb. 26, 2014

(30) Foreign Application Priority Data
Jun. 21, 2013 (CN) 201310250571.6

(51) Int. Cl. G01R 1/067; G09G 3/00

(52) U.S. Cl. CPC G01R 1/06794; G09G 3/006

(57) ABSTRACT

The present disclosure discloses a probe module for detecting the contact performance between the probe module and the external test circuit of the substrate of a LCD panel during liquid crystal alignment. The probe module comprises at least two mutually insulated telescopic probes, a resistance monitoring device which is electrically connected with the at least two mutually insulated telescopic probes, and can monitor the resistance between the at least two mutually insulated telescopic probes to determine the contact performance between the at least two mutually insulated probes and the contact surface. The probe module according to the present disclosure has a plurality of contact points with the target, which are independent from each other. Therefore, the contact performance between the probe and the object can be promptly determined based on the resistance value between a plurality of probes measured by the resistance monitoring device of the probe module. This probe module can save the time in finding the causes of the current abnormality during liquid crystal alignment.

### TECHNICAL FIELD

The present disclosure relates to the manufacturing technology of liquid crystal display (LCD), in particular to a probe module for detecting the contact performance in a process of liquid crystal alignment.

### TECHNICAL BACKGROUND

With thin display being the trend, liquid crystal display (LCD) has been widely used in a variety of electronic products at present, such as mobile phones, laptop computers, color TV sets, and so on.

In the process of manufacturing a LCD panel, it is necessary to conduct an initial alignment to the liquid crystal. Currently, UV Curing is an important procedure for the liquid crystal alignment, under which the alignment is completed by the combined action of an electric field and UV after the LCD panel is filled with liquid crystal.

During the liquid crystal alignment through UV Curing, an electric field is first applied to the liquid crystal, and then the liquid crystal is exposed to UV rays. By means of this process, the reactive monomers of liquid crystal will move upwards and downwards under the electric field, and polymerize under the UV radiation. Thus, alignment layer will be formed on the PI alignment film on the upper and lower substrates of the liquid crystal, thereby achieving the liquid crystal alignment.

It is important to note that, UV, electric field, and reaction temperature are the key factors to implement the above process. Currently, a commonly used source of the electric field is provided by using a group of probe modules to apply an external voltage to the liquid crystal through an external test circuit on the substrate of the LCD panel. Referring to FIG. 1 and FIG. 2, the electric field is generated in the liquid crystal by enabling the probe module 12 to contact the glass substrate 11 and applying the external voltage to the liquid crystal through an external connection line 13 connected to the probe module 12, particularly as shown in FIG. 1.

During the liquid crystal alignment, in order to reduce mura caused by the probes, it is necessary to reduce the number of probes, or to keep the positions where the probes contact the glass substrate away from the display area. However, in this case, substrate deformation e.g., bending might occur, causing poor contact performance when the external voltage is applied to the substrate and further leading to abnormality to the alignment (refer to FIG. 3(a)). Also, unsatisfactory telescopic movement of the probes due to fatigue can also cause contact failure (refer to FIG. 3(b)).

Under the current condition, the deformation of LCD panel is inevitable, thus causing poor contact when the probe module contacts the substrate. Consequently, the preset voltage cannot enter the LCD panel under the controlled conditions, resulting in alignment abnormality and product loss.

To eliminate or alleviate the problem of abnormal alignment caused by poor contact of the probe module, a monitoring device as shown in FIG. 4 is mainly used in the industry to monitor and alert on the electric current between the external power source and a probe module 12. The probe module 12 (FIG. 5) comprises a telescopic probe and a signal line 51 only, wherein the telescopic probe includes a probe body 54, an external probe sleeve 53 covering the probe body 54, and an elastic member 52 which is disposed inside the probe sleeve 53 and can drive the probe body 54 to move in a telescopic manner. A current monitoring unit 42 of the device detects the above-mentioned electric current through a probe line 41. If the detected current is not within the preset scope, an alarm unit 43 of the device will automatically set off alarm.

However, the most common situation is that when the current value detected is relatively large, the probe contact can be basically identified to be good, and the overly large current may be caused by other reasons, such as short circuit inside the LCD panel. However, if the current is relatively small, it may be because of poor probe contact, or another possibility that the internal wiring of the LCD panel is disconnected or partially disconnected, which leads to increased resistance and reduced current.

Therefore, it is impossible to promptly determine whether or not the problem causing the abnormality lies in the probe contact performance, so that operations to solve the abnormality of the device become complex and time-consuming.

Therefore, it is one of the major issues in the industry to find solutions to the above-mentioned problems, so as to quickly and timely confirm the probe contact performance, and to reduce the complexity of the equipment malfunction and time consumption.

### SUMMARY OF THE DISCLOSURE

One of the technical problems to be solved by the present disclosure is to provide a probe module for detecting the contact performance. The probe module can promptly confirm its contact performance with the contact surface during liquid crystal alignment, and reduce the complexity of the equipment malfunction and time consumption.

To solve the above problem, the present disclosure provides a probe module for detecting the contact performance between the probe module and the external test circuit of the substrate of a LCD panel during the liquid crystal alignment. The probe module comprises at least two mutually insulated telescopic probes; resistance monitoring device which is electrically connected with the at least two mutually insulated telescopic probes, and can monitor the resistance between the at least two mutually insulated telescopic probes no as to determine the contact performance between the at least two mutually insulated probes and the contact surface.

In one embodiment, each telescopic probe comprises a probe body, a probe sleeve covering the probe body, and an elastic member which is disposed inside the probe sleeve and can drive the probe body to move in a telescopic manner.

In one embodiment, an insulating layer is provided in part of a space formed between adjacent telescopic probes, and an insulating coating is provided between the adjacent side walls of the probe and the probe sleeve respectively.

In one embodiment, the distance between two adjacent telescopic probes is in a range of 0.1 mm-2 mm.

In one embodiment, when the resistance value measured by the resistance monitoring device is within a first preset range, the at least two mutually insulated telescopic probes are not in contact with the contact surface; and when the resistance value measured by the monitoring device is within a second preset range, the at least two mutually insulated telescopic probes are in contact with the contact surface.

In one embodiment, the probe module further comprises an alarm device, which is electrically connected to the resistance monitoring device, and sets off alarms when the resistance value measured by the resistance monitoring device is in the first preset range.

In one embodiment, the alarm device sets off an alarm by sound or light.

Compared with the prior art, one or more examples of the present disclosure may have the following advantages.

The probe module according to the present disclosure share a plurality of contact points with the contact target, wherein the plurality of contact points are independent from each other, so that the resistance monitoring device with the probe module can promptly determine the contact performance between the probe and the contact target based on the measured resistance value among a plurality of probes. Besides, it is not necessary to further troubleshoot the causes of the abnormality with human labor, so that it is much easier to locate and resolve the abnormal situation, thereby saving the time in finding the causes of the current abnormality as monitored during liquid crystal alignment.

Other features and advantages of the present disclosure will be set forth in the subsequent description and in part will become obvious in the description, or become easier to understand through implementation of the disclosure. The objectives and other advantages of the present disclosure may be achieved in the structure particularly pointed out by the following description, appended claims and accompanying drawings.

### BRIEF DESCRIPTION OF DRAWINGS

The accompanying drawings provide further understanding of the present disclosure and constitute a part of the description to illustrate the present disclosure together with the preferred embodiments; and are not to be construed as limitation to the present disclosure. Wherein:

FIG. 1 is a front view showing a process of liquid crystal alignment using UV curing according to the prior art;

FIG. 2 is a bottom view showing the process of liquid crystal alignment using UV curing according to the prior art;

FIG. 3(a) and FIG. 3(b) are schematic views showing the contact abnormality of the probes in the process of liquid crystal alignment using UV curing;

FIG. 4 schematically shows the structure of a monitoring device for monitoring a probe module according to the prior art;

FIG. 5 schematically shows the structure of the probe module according to the prior art; and

FIG. 6 is a schematic structural view of the probe module according to one embodiment of the present disclosure.

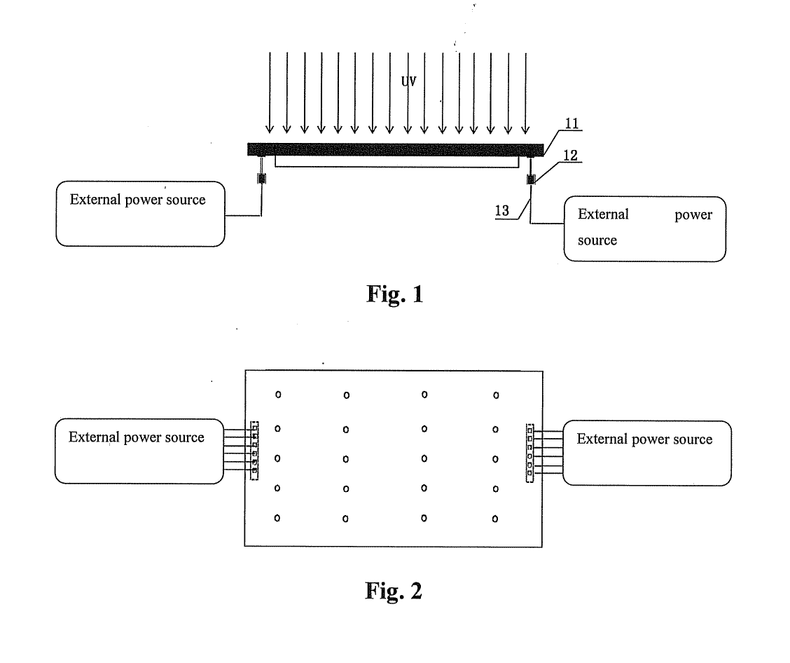

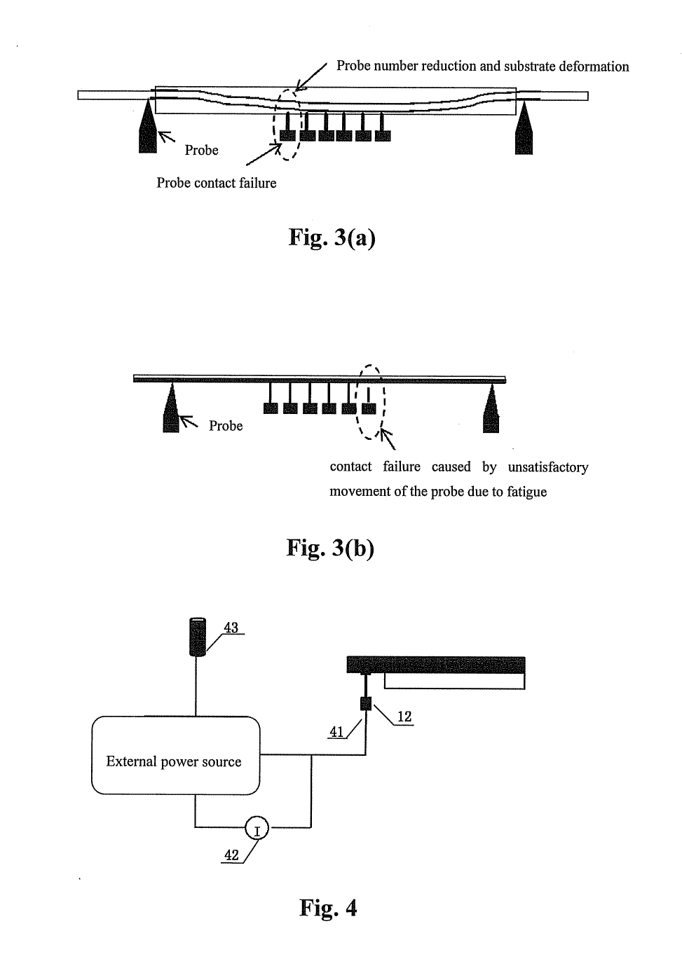

### DETAILED DESCRIPTION OF EMBODIMENTS

To make the objectives, technical solutions, and the advantages of the present disclosure more clear, detailed description of the present disclosure will be given in conjunction with the accompanying drawings.

FIG. 6 schematically shows the structure of a probe module according to an embodiment of the present disclosure. During liquid crystal alignment, the probe module is able to automatically monitor and promptly determine the contact performance between itself and the external test circuit of the substrate.

As shown in FIG. 6, the probe module comprises two mutually insulated telescopic probes, an external power source which is electrically connected with one of the telescopic probes through a signal line 51, a resistance monitoring device 63 which is electrically connected with the other telescopic probe and connected to the external power source, and an alarm device 43 which is electrically connected with the resistance monitoring device 63.

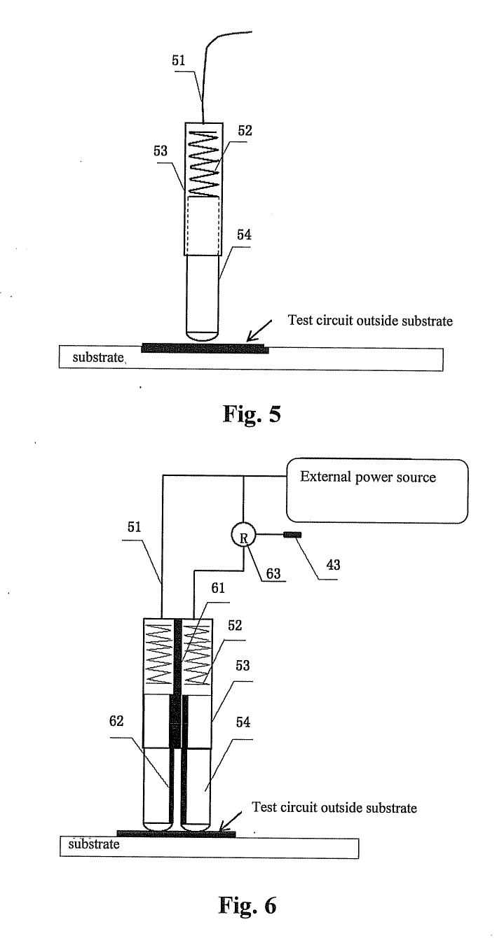

Compared with the conventional probe module as shown in FIG. 5, the probe module according to the present embodiment preferably comprises two similar telescopic probes as mentioned above, such that when the probe module contacts the external test circuit of the substrate, one contact surface may have two contact points which are independent from each other.

Each telescopic probe comprises a probe body 54, a probe sleeve 53 covering the probe body 54, and an elastic member 52, which is provided inside the probe sleeve 53 and can drive the probe body 54 to move in a telescopic manner.

In one preferred embodiment, the two telescopic probes can be insulated with each other by means of providing an insulating layer 61 in part of a space formed between two adjacent telescopic probes, and applying respective insulating coatings 62 on the adjacent side walls of the probe sleeves 53 and the probe bodies 54, respectively. In this manner, short-circuit contact between the two telescopic probes can be prevented. It should be noted that the present disclosure is not limited to the above insulation configuration, and any possible methods that can provide insulation between the two telescopic probes also fall within the scope of the present disclosure.

In addition, the distance between the probes can be set according to actual needs, mainly based on the size of the substrate. The distance is preferably in a range of 0.1 mm-2 mm.

During liquid crystal alignment, the probes of a group of multiple probe modules are brought in contact with the external test circuit of the substrate of a LCD panel, and an electric field is exerted to the liquid crystal via the external power source which is connected to the probe modules. In this process, each probe module can timely measure the resistance between the two probes in this probe module using the resistance monitoring device 63 which is connected to the probes. It should be noted that the resistance can also be regarded as the resistance between the two contact points formed by the two probes contacting the surface.

When the resistance value measured by the resistance monitoring device 63 is within a first preset range, generally in megohm level, then it is determined that both probes of the probe module are not in contact with the contact surface. This is because when neither of the two probes is in contact with the contact surface, the two probes will form an open circuit and thus the resistance between them will be very large. When the resistance value measured by the resistance monitoring device 63 is within a second preset range, generally in a level of hundreds or thousands of ohms, it is determined that both probes are in good contact with the contact surface. This is because the contact surface is a metal layer, and thus the region between two probes is conductive, resulting in a certain resistance (which is much smaller relative to the situation where the two probes are not in contact with the surface). Therefore, the contact performance between the probes and the contact surface can be determined by measuring the changes in resistance using the monitoring device 63.

When the resistance value measured by the resistance monitoring device 63 is in the first preset range, i.e., it is determined that the two probes of the probe module are not in contact with the contact surface, the alarm device 43 may set off alarms to the operator of the abnormality by means of noise or voice. In addition, the alarm device 43 can also be implemented as an indicator lamp, which can inform the operator about the contact performance at the moment with lights of different colors. For example, red light indicates a loss of contact, and green light indicates a good contact. In this case, the operator can be sure of the contact performance between the probe module and the panel.

During liquid crystal alignment, the above probe module is able to indicate the contact performance of its probes with the target, thus no human labor is needed to troubleshoot the causes of the abnormality. Compared with the probe of the conventional probe module (see FIG. 5) which has only one contact point with the target, the probe module according to the present embodiment has two contact points with the target which are independent from each other. And with the resistance monitoring device, the resistance between the two contact points can be monitored, and thus the contact performance between the probes and the contact object can be determined according to the value of resistance. That means, when the resistance suddenly becomes small to a certain extent, good contact can be recognized; however, when the resistance does not change to a certain extent, or does not change at all, poor contact can be confirmed.

Of course, the above can be only understood as a preferred embodiment of the present disclosure. The number of probes of a probe module is not limited to two, and there may be three or more than three probes arranged in parallel. When the probe module comprises three or more probes, the signal line 51 and the resistance monitoring device 63 can be electrically connected respectively to the outermost probes of the probe module, and probes are insulated with each other.

Although the present disclosure has been illustrated with preferred embodiments, various modifications can be made and the components in the present disclosure can be substituted with equivalents without departing from the scope of the present disclosure. In particular, as long as there is no structural conflict, the technical features of each embodiment can be combined in any way. The disclosure is not limited to the specific embodiments disclosed herein, but rather includes all the technical solutions within the scope of the appended claims.

1. A probe module for detecting the contact performance between the probe module and an external test circuit of the substrate of a LCD panel during liquid crystal alignment, comprising:
at least two mutually insulated telescopic probes; and
a resistance monitoring device, which is electrically connected with the at least two mutually insulated telescopic probes, and can monitor the resistance between the at least two mutually insulated telescopic probes so as to determine the contact performance between the at least two mutually insulated probes and a contact surface.

2. The probe module according to claim 1, wherein each telescopic probe comprises a probe body, a probe sleeve covering the probe body, and an elastic member which is disposed inside the probe sleeve and can drive the probe body to move in a telescopic manner.

3. The probe module according to claim 2, wherein an insulating layer is provided in part of a space formed between adjacent telescopic probes, and an insulating coating is provided between adjacent side walls of the probe and the probe sleeve respectively.

4. The probe module according to claim 3, wherein the distance between two adjacent telescopic probes is in a range of 0.1 mm-2 mm.

5. The probe module according to claim 1, wherein,
the resistance value measured by the resistance monitoring device is within a first preset range, the at least two mutually insulated telescopic probes are not in contact with the contact surface; and
the resistance value measured by the monitoring device is within a second preset range, the at least two mutually insulated telescopic probes are in contact with the contact surface.

6. The probe module according to claim 5, wherein further comprises an alarm device, which is electrically connected to the resistance monitoring device, and sets off alarms when the resistance value measured by the resistance monitoring device is in the first preset range.

7. The probe module according to claim 6, wherein the alarm device sets off an alarm by sound or light.
